(19) United States
(12) Patent Application Publication
(10) Pub. No.: US 2024/0357743 A1
(43) Pub. Date: Oct. 24, 2024

(54) CIRCUIT MODULE

(71) Applicant: Murata Manufacturing Co., Ltd., Nagaokakyo-shi (JP)

(72) Inventor: Hiromasa YABUKI, Nagaokakyo-shi (JP)

(21) Appl. No.: 18/679,211

(22) Filed: May 30, 2024

Related U.S. Application Data
(63) Continuation of application No. PCT/JP2022/039103, filed on Oct. 20, 2022.

(30) Foreign Application Priority Data
Dec. 1, 2021 (JP) 2021-195569

(51) Int. Cl. H05K 1/11

(52) U.S. Cl. CPC H05K 1/11

(57) ABSTRACT

A circuit module that includes: a substrate; a stud electrode on a surface of the substrate; a molding resin on the surface of the substrate and covering a periphery of the stud electrode, the molding resin including: a first main surface adjacent the surface of the substrate; and a second main surface opposed to the first main surface, the molding resin including a recess in the second main surface, the recess being located such that an end surface and a side surface of the stud electrode are exposed in the recess from the molding resin; and a plating layer on the exposed side surface of the stud electrode.

### CROSS REFERENCE TO RELATED APPLICATIONS

The present application is a continuation of International application No. PCT/JP2022/039103, filed Oct. 20, 2022, which claims priority to Japanese Patent Application No. 2021-195569, filed Dec. 1, 2021, the entire contents of each of which are incorporated herein by reference.

### TECHNICAL FIELD

The present description relates to a circuit module.

### BACKGROUND ART

A circuit module is widely used in which components are mounted on a substrate and are covered with a molding resin from above.

In such a circuit module, a stud electrode is used to connect a circuit formed on the substrate to an external electronic component.

Specifically, the circuit module is manufactured such that an end part of the stud electrode on the substrate side is connected to the circuit formed on the substrate and such that the other end part is exposed from the molding resin.

By mounting the circuit module on an external electronic component via the other end part of the stud electrode, it is possible to electrically connect the circuit formed on the substrate and the external electronic component.

As such a circuit module, Patent Literature 1 discloses the following module (circuit module). A module includes: a substrate including a first surface; a first component and a second component mounted on the first surface; a first conductive member (stud electrode) mounted between the first component and the second component on the first surface; a first sealing resin (molding resin) formed on the first surface so as to cover the first component, the second component, and the first conductive member (stud electrode); and a first shield film that covers a surface of the first sealing resin (molding resin) on a far side with respect to the substrate, wherein the first sealing resin (molding resin) has a recess that allows at least a part of the first conductive member (stud electrode) to be exposed, and the first shield film extends along an inner surface of the recess and is thereby electrically connected to the first conductive member (stud electrode), an opening is provided in the first shield film in the recess, an opening is provided in the first shield film, a metal bump is disposed in the recess, and the metal bump is electrically connected to the first conductive member (stud electrode) through the opening.
Patent Literature 1: WO 2021/090694

### SUMMARY OF THE DESCRIPTION

In the module (circuit module) described in Patent Literature 1, a solder bump is used when the first conductive member (stud electrode) is connected to an external electronic component.

There is a problem as described below. When a stress occurs due to thermal shock, drop shock, or the like in a state where the module (circuit module) described in Patent Literature 1 and an external electronic component are connected to each other, the solder bump easily peels off from the first conductive member (stud electrode).

The present description has been made to solve the above problem, and an object of the present description is to provide a circuit module in which a solder bump hardly peels off from a stud electrode.

A circuit module of the present description includes: a substrate; a stud electrode on a surface of the substrate; a molding resin on the surface of the substrate and covering a periphery of the stud electrode, the molding resin including: a first main surface adjacent the surface of the substrate; and a second main surface opposed to the first main surface, the molding resin including a recess in the second main surface, the recess being located such that an end surface and a side surface of the stud electrode are exposed in the recess from the molding resin; and a plating layer on the exposed side surface of the stud electrode.

The present description can provide a circuit module in which a solder bump hardly peels off from a stud electrode.

### BRIEF DESCRIPTION OF THE DRAWINGS

FIG. 1A is a cross-sectional view schematically illustrating an example of a circuit module according to Embodiment 1 of the present description.

FIG. 1B is a cross-sectional view schematically illustrating an example of a state in which solder bumps are disposed on stud electrodes of the circuit module according to Embodiment 1 of the present description.

FIG. 2 is a process diagram schematically illustrating an example of a ceramic green sheet preparation step in a method for manufacturing the circuit module according to Embodiment 1 of the present description.

FIG. 3 is a process diagram schematically illustrating an example of a stud electrode constraint layer preparation step in the method for manufacturing the circuit module according to Embodiment 1 of the present description.

FIG. 4 is a process diagram schematically illustrating an example of a stud electrode constraint layer laminating step in the method for manufacturing the circuit module according to Embodiment 1 of the present description.

FIG. 5 is a process diagram schematically illustrating an example of a baking step in the method for manufacturing the circuit module according to Embodiment 1 of the present description.

FIG. 6 is a process diagram schematically illustrating an example of a stud electrode constraint layer removal step in the method for manufacturing the circuit module according to Embodiment 1 of the present description.

FIG. 7 is a process diagram schematically illustrating an example of a plating step in the method for manufacturing the circuit module according to Embodiment 1 of the present description.

FIG. 8 is a process diagram schematically illustrating an example of an electronic component disposing step in the method for manufacturing the circuit module according to Embodiment 1 of the present description.

FIG. 9 is a process diagram schematically illustrating an example of a resin sealing step in the method for manufacturing the circuit module according to Embodiment 1 of the present description.

FIG. 10 is a process diagram schematically illustrating an example of a polishing step in the method for manufacturing the circuit module according to Embodiment 1 of the present description.

FIG. 11A is a process diagram schematically illustrating an example of a stud electrode exposing step in the method for manufacturing the circuit module according to Embodiment 1 of the present description.

FIG. 11B is a plan view of a second main surface of a molding resin schematically illustrating an example of laser irradiation positions in the stud electrode exposing step.

FIG. 12A is a cross-sectional view schematically illustrating an example of a state in which solder bumps are disposed on the circuit module according to Embodiment 1 of the present description.

FIG. 12B is a cross-sectional view schematically illustrating an example of a state in which the solder bumps disposed on the circuit module according to Embodiment 1 of the present description are melted by reflow.

FIG. 13 is a cross-sectional view schematically illustrating an example of a modification of the circuit module according to Embodiment 1 of the present description.

FIG. 14 is a cross-sectional view schematically illustrating an example of another modification of the circuit module according to Embodiment 1 of the present description.

FIG. 15 is a cross-sectional view schematically illustrating example of a circuit module according to Embodiment 2 of the present description.

FIG. 16 is a cross-sectional view schematically illustrating an example of a circuit module according to another embodiment of the present description.

### DESCRIPTION OF THE PREFERRED EMBODIMENTS

Hereinafter, a circuit module of the present description is set forth.

However, the present description is not limited to the following configuration, and can be appropriately modified and applied without changing the gist of the present description.

A combination of two or more of individual preferred configurations of the present description set forth below is also included in the present description.

A circuit module of the present description includes: a substrate; a stud electrode on a surface of the substrate; a molding resin on the surface of the substrate and covering a periphery of the stud electrode, the molding resin including: a first main surface adjacent the surface of the substrate; and a second main surface opposed to the first main surface, the molding resin including a recess in the second main surface, the recess being located such that an end surface and a side surface of the stud electrode are exposed in the recess from the molding resin; and a plating layer on the exposed side surface of the stud electrode.

As long as the circuit module of the present description includes the above configuration, the circuit module may include other configurations within such a range that the effects of the present description are exhibited.

Each embodiment shown below is an example, and it goes without saying that partial replacement or combination of configurations described in different embodiments is possible. In Embodiment 2 and the subsequent embodiment, the matters common to Embodiment 1 will not be described, and only the differences is described. In particular, the same operation and effect by the same configuration will not be mentioned each time in each embodiment.

### Embodiment 1

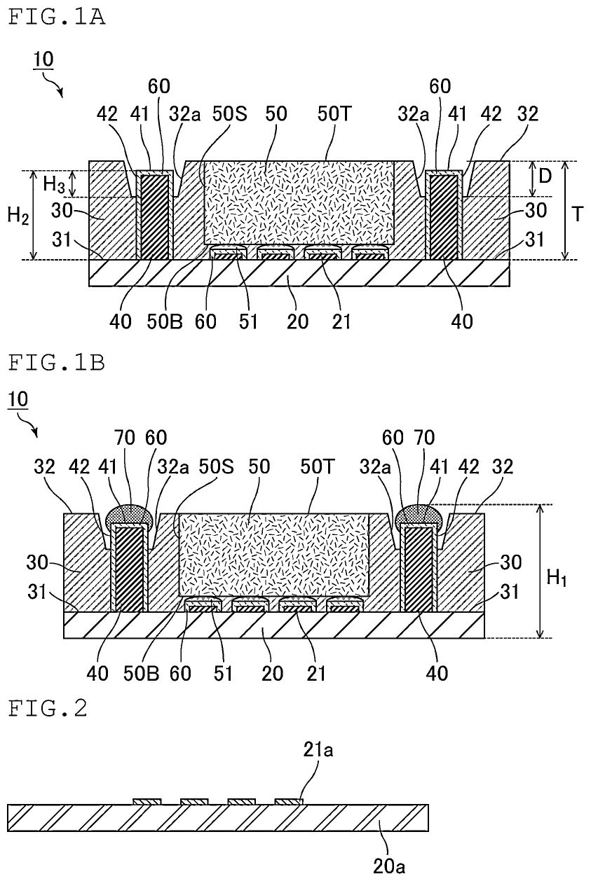

FIG. 1A is a cross-sectional view schematically illustrating an example of a circuit module of Embodiment 1.

A circuit module 10 illustrated in FIG. 1A includes a substrate 20, a molding resin 30 that is disposed on a surface of the substrate 20 and has a first main surface 31 in contact with the surface of the substrate 20 and a second main surface 32 opposed to the first main surface 31; and stud electrodes 40 that are disposed on the surface of the substrate 20 and each include a periphery covered with the molding resin 30.

Although not illustrated in FIG. 1A, a wiring is formed on the substrate 20, and the wiring is connected to the stud electrodes 40.

In the circuit module 10, an electronic component 50 is disposed on electrodes 21 formed on the surface of the substrate 20, via connection members 51. In the electronic component 50, a bottom surface 50B connected to the electrodes 21 and side surfaces 50S are covered with the molding resin 30, and an upper surface 50T is exposed from the molding resin 30.

The upper surface 50T of the electronic component 50 is located on the same plane as the second main surface 32 of the molding resin 30.

The molding resin 30 has recesses 32a each formed such that a part of the second main surface 32 is recessed.

In the recesses 32a, each of the stud electrodes 40 has an exposed end surface 41 and an exposed side surface 42 exposed from the molding resin 30.

Plating layers 60 are formed on the electrodes 21 and the surfaces of the stud electrodes 40 including the exposed end surfaces 41 and the exposed side surfaces 42.

In the circuit module 10, the exposed end surfaces 41 are located closer to the substrate 20 as compared to the second main surface 32 of the molding resin 30.

Here, effects of the circuit module 10 are described.

FIG. 1B is a cross-sectional view schematically illustrating an example of a state in which solder bumps are disposed on the stud electrodes of the circuit module according to Embodiment 1 of the present description.

As illustrated in FIG. 1B, in the circuit module 10, solder bumps 70 are disposed in the recesses 32a of the second main surface 32.

When the solder bumps 70 are disposed, the solder bumps 70 are heated to be melted and thereby connected to the stud electrodes 40.

When the solder bumps 70 are melted, the solder bumps wet-spread not only to the exposed end surfaces 41 of the stud electrodes 40 but also to the exposed side surfaces 42.

Thereafter, the solder bumps 70 are cooled and solidified, and the solder bumps 70 are connected not only to the exposed end surfaces 41 of the stud electrodes 40 but also to the exposed side surfaces 42.

In the conventional circuit module, only the end surfaces of the stud electrodes are exposed from the molding resin. Therefore, when the solder bumps are disposed in the conventional circuit module, the solder bumps are connected only to the end parts of the stud electrodes.

However, in the circuit module 10, as described above, the solder bumps 70 are connected not only to the exposed end surfaces 41 of the stud electrodes 40 but also to the exposed side surfaces 42. Therefore, the contact areas between the solder bumps 70 and the stud electrodes 40 are larger than in the case where the solder bumps are disposed in the conventional circuit module.

Therefore, the solder bumps 70 are hardly peeled off from the stud electrodes 40.

Further, each solder bump 70 continuously covers both the exposed end surface 41 and the exposed side surface 42 of the corresponding stud electrode 40. Specifically, the solder bump 70 bridges over a corner part of the stud electrode 40 so as to cover both the exposed end surface 41 and the exposed side surface 42. When the solder bump 70 covers the stud electrode 40 in this manner, the area of the interface can be increased. Further, the interface between the solder bump 70 and the stud electrode 40 is bent at the corner part of the stud electrode 40 and is therefore not formed in a planar shape.

Therefore, even when stress occurs at the interface between the solder bump 70 and the stud electrode 40, the stress can be received at a plurality of parts, and the stress hardly concentrates. In particular, stress is likely to concentrate on the corner part of the stud electrode 40; however, since the solder bump 70 covers the stud electrode 40 so as to bridge over the corner part of the stud electrode 40, the stress is less likely to concentrate.

Also for this reason, the solder bump 70 is hardly peeled off from the stud electrode 40.

In the circuit module 10, a plating layer 60 is formed on the exposed end surface 41 and the exposed side surface 42 of each stud electrode 40.

By providing such plating layer 60, it is possible to improve wettability of the corresponding solder bump 70. Therefore, the solder bump 70 can be made less likely to be peeled off from the stud electrode 40.

In the circuit module 10, the exposed end surfaces 41 are located closer to the substrate 20 as compared to the second main surface 32 of the molding resin 30 is.

When the solder bumps 70 are disposed in the recesses 32a, the bottom parts of the solder bumps 70 are in contact with respective ones of the exposed end surfaces 41 of the stud electrodes 40.

Since, as described above, the exposed end surfaces 41 are located closer to the substrate 20 as compared to the second main surface 32 of the molding resin 30, the solder bumps 70 enter the recesses 32a.

Thus, the distance from the bottom part of the substrate 20 to the top of each solder bump 70 can be made shorter. That is, it is possible to reduce a height (a height denoted by a reference sign “H₁” in FIG. 1B) of the circuit module 10 when the solder bumps 70 are disposed.

Hereinafter, each component of the circuit module 10 is described in detail.

### (Substrate)

The substrate 20 is not limited, but is preferably a ceramic substrate formed by baking a ceramic green sheet made of a low temperature co-fired ceramic (LTCC) material. The low temperature co-fired ceramic material is a type of ceramic material, and is a ceramic material that can be fired at a temperature of 1000° C. or lower and can be co-fired with Au, Ag, Cu, or the like having a small specific resistance. Specific examples of the low temperature co-fired ceramic material include the following materials: glass composite low temperature co-fired ceramic material in which borosilicate glass is mixed with a ceramic powder such as alumina, zirconia, magnesia, or forsterite; crystallized glass low temperature co-fired ceramic material using ZnO—MgO—Al₂O₃—SiO₂ crystallized glass; and non-glass low-temperature co-fired ceramic material using BaO—Al₂O₃—SiO₂ ceramic powder, Al₂O₃—CaO—SiO₂—MgO—B₂O₃ ceramic powder, or the like.

The substrate 20 preferably has a thickness of, for example, 5 μm to 100 μm.

As illustrated in FIG. 1A, the plating layers 60 are formed on the electrodes 21 disposed on the surface of the substrate 20.

The electrodes 21 are preferably made of a metal material such as Cu or a Cu alloy. The plating layers 60 formed on the electrodes 21 are preferably made of a metal material such as Ni or a Ni alloy.

Note that, in FIG. 1A, a single-layer substrate is illustrated as the substrate 20 of the circuit module 10, but in the circuit module of the present description, the substrate may be a laminated substrate in which a plurality of substrates are laminated. In addition, internal electrodes and vias may be formed inside the laminated substrates.

In the circuit module of the present description, another substrate may be further laminated under the substrate 20. The another substrate may be a ceramic substrate or may be a resin substrate.

### (Molding Resin)

The molding resin is preferably a resin composition in which a glass material, silica, or another material is dispersed, as a filler, in a resin material.

As the resin material, an epoxy resin, silicone, a phenol resin, or another resin can be used.

A thickness (a thickness denoted by a reference sign “T” in FIG. 1A) of the molding resin 30 is preferably set appropriately in accordance with a usage of the circuit module, and is preferably, for example, 0.05 mm to 0.30 mm.

The molding resin 30 has recesses 32a each formed such that a part of the second main surface 32 is recessed.

By forming the recesses 32a, the side surfaces of the stud electrodes 40 can be exposed, and the exposed side surfaces 42 can therefore be formed.

The shape of the recesses 32a is not limited, and may be a circular shape, an elliptical shape, a triangular shape, a quadrangular shape, a pentagonal shape, a hexagonal shape, an octagonal shape, or another shape when viewed from the direction perpendicular to the second main surface 32.

In addition, an area inside a contour of a bottom surface of the recesses 32a on the second main surface 32 as viewed from the direction perpendicular to the second main surface 32 is preferably set appropriately in accordance with a size of the stud electrodes 40 and the like, and is preferably, for example, 0.03 mm² to 0.30 mm².

The recesses 32a have a tapered shape in which a wall surface is formed obliquely with respect to the bottom surface in FIG. 1A, but in the circuit module of the present description, each recess may have a bottom surface and a wall surface, and the bottom surface and the wall surface may be orthogonal to each other.

The depth (a depth denoted by a reference sign “D” in FIG. 1A) of the recesses 32a in a thickness direction of the molding resin 30 is preferably 10% to 50%, more preferably 20% to 45%, of the thickness T of the molding resin 30.

When the depth of the recesses is less than 10% of the thickness T of the molding resin, the area of the exposed side surface of each stud electrode is smaller, and it is difficult to obtain the effect that the solder bumps are hardly peeled off from the stud electrodes.

When the depth of the recesses exceeds 50% of the thickness T of the molding resin, processing difficulty of forming the recesses is higher, and productivity of the circuit module tends to be decreased. In addition, when such recesses are formed by laser processing, high output is required, and the plating layer formed on the stud electrodes may be damaged. Furthermore, it is difficult to remove a resin residue by a desmear treatment.

### (Stud Electrode)

A material constituting the stud electrodes 40 is not limited, and, for example, a metal material such as Cu or a Cu alloy can be used. Examples of the Cu alloy include a Cu-10Ni alloy.

The stud electrodes 40 are preferably a sintered body in which a powder of such metals is sintered.

In a case where the substrate 20 is a ceramic substrate, such stud electrodes 40 can also be collectively formed when the ceramic substrate is sintered and formed. Therefore, since it is possible to reduce the number of times of heating in the process of manufacturing the circuit module 10, it is possible to reduce heat-induced damage to the circuit module 10.

A shape of the stud electrodes 40 is not limited, and may be a columnar shape, an elliptic columnar shape, a triangular columnar shape, a square columnar shape, a pentagonal columnar shape, a hexagonal columnar shape, or an octagonal columnar shape.

Among these shapes, a columnar shape is preferable.

An area of the exposed end surface 41 of each stud electrode 40 is preferably 0.10 mm² to 0.28 mm², more preferably 0.13 mm² to 0.26 mm².

A height (a height denoted by a reference sign “H” in FIG. 1A) of each stud electrode 40 is preferably 0.055 mm to 0.290 mm, more preferably 0.060 mm to 0.280 mm.

A height (a height denoted by “H₃” in FIG. 1A) of the exposed side surfaces 42 of the stud electrodes 40 in the thickness direction of the molding resin 30 is preferably 5% to 30%, more preferably 10% to 25%, of the thickness T of the molding resin 30.

When the height H₃ of the exposed side surfaces is less than 5% of the thickness T of the molding resin, the area of each exposed side surface is smaller, and it is difficult to obtain the effect that the solder bumps are hardly peeled off from the stud electrodes.

To set the height H₃ of the exposed side surface 42 larger than 30% of the thickness T of the molding resin 30, it is necessary to form the recesses deeply. However, when such deep recesses are formed, the degree of processing difficulty is higher, and the productivity of the circuit module tends to be decreased.

The height H₃ of the exposed side surfaces 42 of the stud electrodes 40 in the thickness direction of the molding resin 30 is preferably 20% to 80% of the depth D of the recesses 32a.

Within such a range, the exposed side surfaces 42 of the stud electrodes 40 and the solder bumps 70 can be suitably connected.

### (Plating Layer)

The plating layers 60 formed on the stud electrodes 40 are not limited, but are preferably formed of a metal such as Ni, Au, Cu, Pd, Ag, or Sn, or an alloy of these metals.

When the plating layers 60 are made of these metals, wettability of the solder bumps 70 is improved.

As a result, the solder bumps 70 are each suitably connected to the exposed end surface 41 and the exposed side surface 42 of the corresponding one of the stud electrodes 40.

In addition, the stud electrodes 40 can be protected by the plating layers 60 and prevented from corrosion and the like.

The plating layers 60 may be formed by electroless plating or formed by electrolytic plating.

The thickness of the plating layers 60 is preferably 2 μm to 15 μm.

Within such a range, the plating layers 60 can suitably protect the stud electrodes 40, and can prevent corrosion and the like.

### (Electronic Component)

The electronic component 50 is preferably, for example, a chip component such as a multilayer capacitor, a multilayer inductor, or various filters, or a semiconductor component such as various ICs or memories.

The electronic component 50 is connected to the electrodes 21, and a connection method thereof is not limited, and may be connected by connection members made of, for example, Sn—Ag—Cu Pb-free solder.

### (Solder Bump)

As the solder bumps 70, a conventionally used known solder bumps can be used.

As such solder bumps 70, for example, Sn—Ag—Cu Pb-free solder can be used.

Next, a method for manufacturing the circuit module 10 is described.

The following manufacturing method describes a case of preparing a ceramic substrate in which an LTCC material is used as the substrate.

The method for manufacturing the circuit module 10 may include a ceramic green sheet preparation step, a stud electrode constraint layer preparation step, a stud electrode constraint layer laminating step, a baking step, a stud electrode constraint layer removal step, a plating step, an electronic component disposing step, a resin sealing step, a polishing step, and a stud electrode exposing step.

### (Ceramic Green Sheet Preparation Step)

FIG. 2 is a process diagram schematically illustrating an example of the ceramic green sheet preparation step in the method for manufacturing the circuit module according to Embodiment 1 of the present description.

In the method for manufacturing the circuit module 10, a slurry is prepared by mixing arbitrary amounts of the following materials: an LTCC material; a binder; and a plasticizer.

Next, the slurry is applied onto a carrier film to form a ceramic green sheet 20a illustrated in FIG. 2. A lip coater or a doctor blade can be used to apply the slurry. The ceramic green sheet is preferably formed of the slurry having a thickness of 5 to 100 μm.

Next, a conductive powder, a plasticizer, and a binder are mixed to prepare a conductive paste for circuit formation, and the conductive paste for circuit formation is printed on a surface of the ceramic green sheet 20a to form an unfired body (not shown) of a wiring pattern and unfired bodies 21a for the electrodes.

Examples of the printing method include screen printing, inkjet printing, and gravure printing.

Through the above steps, the ceramic green sheet 20a illustrated in FIG. 2 can be prepared.

### (Stud Electrode Constraint Layer Preparation Step)

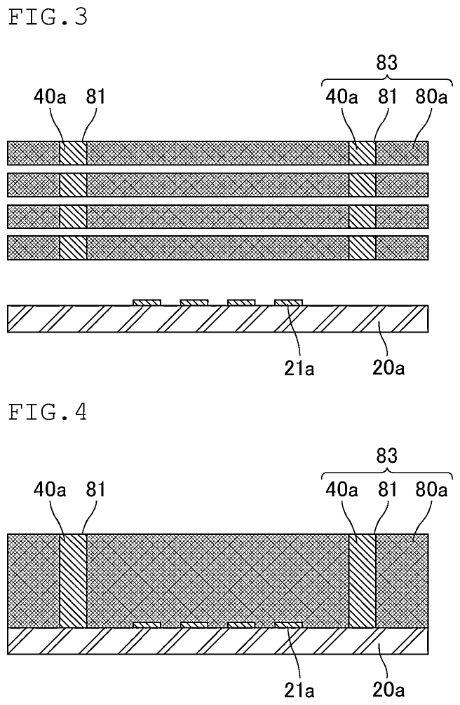

FIG. 3 is a process diagram schematically illustrating an example of the stud electrode constraint layer preparation step in the method for manufacturing the circuit module according to Embodiment 1 of the present description.

Next, a slurry is prepared by mixing an LTCC material, a sintering-resistant ceramic material powder, a binder, and a plasticizer. As the sintering-resistant ceramic material powder, Al₂O₃ can be used, for example.

The sintering-resistant ceramic material is not substantially sintered at a sintering temperature for the LTCC material and is brittle even after baking, and stud electrode constraint layers can be easily removed in the stud electrode constraint layer removal step described later.

Next, the slurry is applied onto carrier films to form a plurality of constraining-layer green sheets 80a. A lip coater or a doctor blade can be used to apply the slurry. The constraining-layer green sheets 80a are each preferably formed of the slurry having a thickness of 5 μm to 100 μm.

Thereafter, the through-holes 81 are formed in the constraining-layer green sheets 80a. The through-holes 81 are formed at the positions exactly overlapping each other when the constraining-layer green sheets 80a have been laminated.

Next, a conductive powder, a plasticizer, and a binder are mixed to prepare a stud electrode forming conductive paste.

Thereafter, as illustrated in FIG. 3, the through-holes 81 of the constraining-layer green sheets 80a are filled with a stud electrode forming conductive paste 40a to produce a plurality of stud electrode constraint layers 83.

The filling with the stud electrode forming conductive paste 40a can be performed by a known method such as screen printing.

### (Stud Electrode Constraint Layer Laminating Step)

FIG. 4 is a process diagram schematically illustrating an example of the stud electrode constraint layer laminating step in the method for manufacturing the circuit module according to Embodiment 1 of the present description.

Next, as illustrated in FIG. 4, the ceramic green sheet 20a and the stud electrode constraint layers 83 are laminated.

At this time, the stud electrode forming conductive pastes 40a disposed in each of the stud electrode constraint layers 83 are aligned so as to overlap a circuit (not shown) formed on the ceramic green sheet 20a.

### (Baking Step)

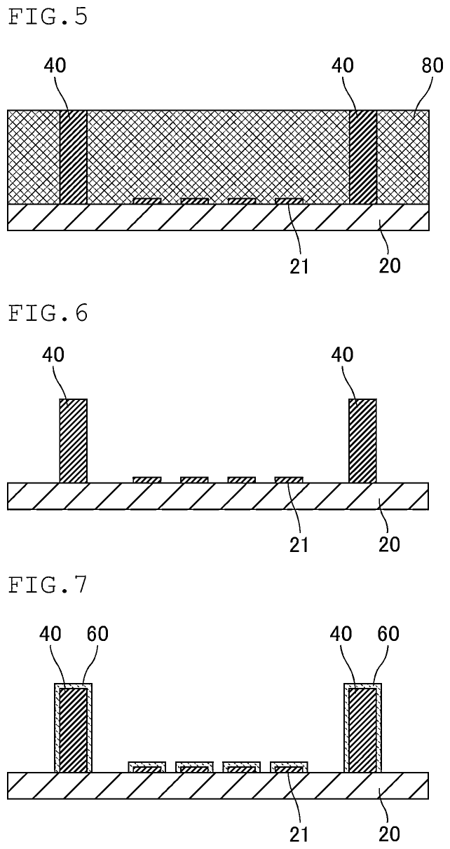

FIG. 5 is a process diagram schematically illustrating an example of the baking step in the method for manufacturing the circuit module according to Embodiment 1 of the present description.

Next, the laminated ceramic green sheet 20a and the stud electrode constraint layers 83 are baked.

The baking conditions are not limited, and are preferably set appropriately in accordance with the materials, shapes, and the like of the ceramic green sheets, the conductive paste for circuit formation, and the stud electrode forming conductive paste.

Note that, when the conductive paste for circuit formation and the stud electrode forming conductive paste contain a copper compound, the baking is preferably performed in a reducing atmosphere.

As a baking furnace for baking, a batch furnace or a belt furnace can be used.

Through such steps, the ceramic green sheet 20a, the unfired bodies 21a for the electrodes, and the stud electrode forming conductive pastes 40a are baked and become the substrate 20, the electrodes 21, and the stud electrodes 40 as illustrated in FIG. 5. The constraining-layer green sheets 80a are also baked and become a baked constraining-layer sheet 80.

The height of the stud electrodes 40 can be adjusted by changing the thickness and the number of the stud electrode constraint layers 83.

In this step, the positions of the head parts of the stud electrodes 40 to be formed are made lower than the height of a head part of the electronic component 50 disposed on a substrate described later.

In the above method, the substrate 20, the electrodes 21, and the stud electrodes 40 are collectively formed by a single baking treatment. Therefore, the number of times of heating can be reduced to manufacture the circuit module 10.

In the above method, the plurality of stud electrode constraint layers 83 are laminated to form the stud electrodes 40; therefore, the stud electrodes 40 can be easily formed at accurate positions.

### (Stud Electrode Constraint Layer Removal Step)

FIG. 6 is a process diagram schematically illustrating an example of the stud electrode constraint layer removal step in the method for manufacturing the circuit module according to Embodiment 1 of the present description.

Next, as illustrated in FIG. 6, the baked constraining-layer sheet 80 is removed. As the method for removing the baked constraining-layer sheet 80 is not limited, and a known method such as sandblast can be adopted.

### (Plating Step)

FIG. 7 is a process diagram schematically illustrating an example of the plating step in the method for manufacturing the circuit module according to Embodiment 1 of the present description.

Next, the surfaces of the stud electrodes 40 and the electrodes 21 are subjected to a plating treatment. By the plating treatment, as illustrated in FIG. 7, the plating layers 60 can be formed on the surfaces of the stud electrodes 40 and the electrodes 21.

The method for forming the plating layers 60 is not limited, and the plating layers 60 are preferably formed by a known electroless plating method.

### (Electronic Component Disposing Step)

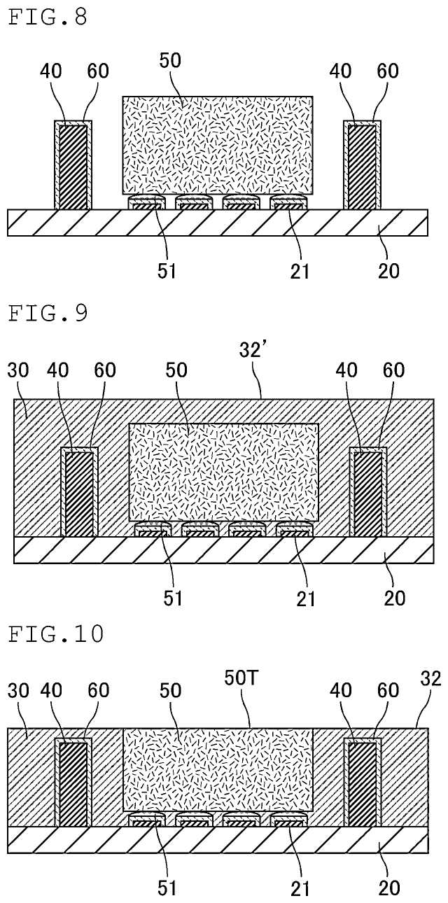

FIG. 8 is a process diagram schematically illustrating an example of the electronic component disposing step in the method for manufacturing the circuit module according to Embodiment 1 of the present description.

Next, as illustrated in FIG. 8, the electronic component 50 is connected to the electrodes 21 and thus disposed on the substrate 20. At this time, the electronic component 50 and the electrodes 21 are preferably connected by a connection members 51 made of, for example, Sn—Ag—Cu Pb-free solder.

### (Resin Sealing Step)

FIG. 9 is a process diagram schematically illustrating an example of the resin sealing step in the method for manufacturing the circuit module according to Embodiment 1 of the present description.

Next, the molding resin 30 is applied onto the substrate 20 such that the stud electrodes 40 and the electronic component 50 connected to the electrodes 21 are entirely covered.

A known method can be adopted for the application of the molding resin 30.

A part of the molding resin 30 in contact with the surface of the substrate 20 is the first main surface 31. The main surface opposed to the first main surface 31 is a pre-second main surface 32′.

### (Polishing Step)

FIG. 10 is a process diagram schematically illustrating an example of the polishing step in the method for manufacturing the circuit module according to Embodiment 1 of the present description.

Next, the molding resin 30 is polished from the pre-second main surface 32′ side. At this time, a part of the electronic component 50 is also polished together. The head parts of the stud electrodes 40 are not polished.

The polished surface of the molding resin 30 after polishing is the second main surface 32.

By performing the polishing step, the second main surface 32 and the upper surface 50T of the electronic component 50 can be positioned on the same plane.

As the polishing method, a known method such as lap polishing can be adopted.

### (Stud Electrode Exposing Step)

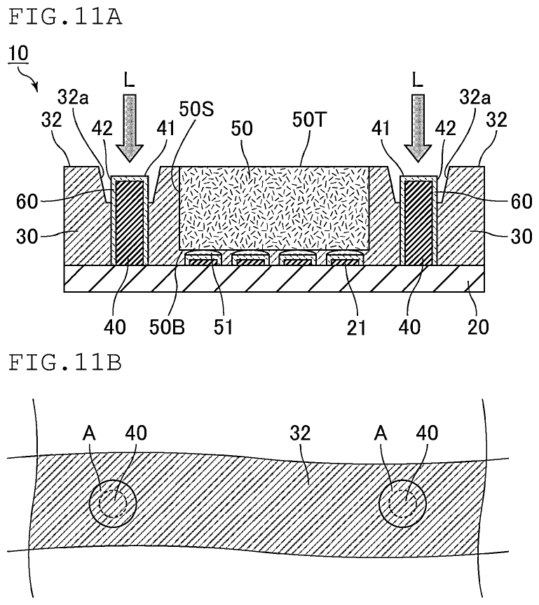

FIG. 11A is a process diagram schematically illustrating an example of the stud electrode exposing step in the method for manufacturing the circuit module according to Embodiment 1 of the present description.

Next, by irradiating the second main surface 32 of the molding resin 30 with laser L, parts of the molding resin 30 are decomposed to form the recesses 32a. At this time, the recesses are formed such that a part of each stud electrode 40 is exposed.

The exposed head parts of the stud electrodes 40 are the exposed end surfaces 41, and the exposed side surfaces of the stud electrodes 40 are the exposed side surfaces 42.

Here, laser irradiations areas is described with reference to a drawing.

FIG. 11B is a plan view of the second main surface of the molding resin schematically illustrating an example of the laser irradiation positions in the stud electrode exposing step.

As illustrated in FIG. 11B, on the second main surface 32, areas A that are to be irradiated with laser are preferably the areas (areas denoted by reference signs “A” in FIG. 11B) each covering a contour of the corresponding buried stud electrode 40. By irradiating such areas with laser, the side surfaces of the stud electrodes 40 can also be exposed.

As the laser, for example, YAG laser can be used.

In addition, the output of the laser is preferably adjusted to such an extent that the laser can decompose the molding resin 30 but does not damage the plating layers 60 formed on the exposed end surfaces 41 and the exposed side surfaces 42 of the stud electrodes 40 or the stud electrodes 40.

After the irradiation with laser, the parts irradiated with the laser are preferably cleaned by a desmear treatment or the like to remove foreign matters.

The circuit module 10 can be manufactured through the above steps.

Next, a method for disposing the solder bumps 70 on the stud electrodes 40 of the manufactured circuit module 10 is described.

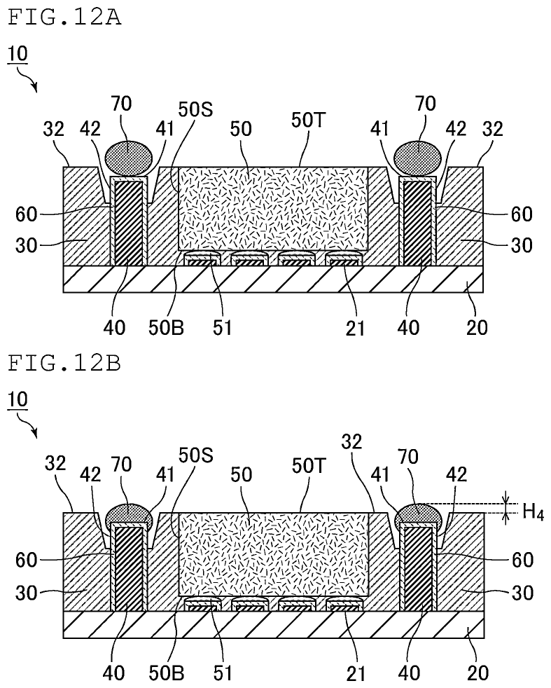

FIG. 12A is a cross-sectional view schematically illustrating an example of a state in which the solder bumps are disposed on the circuit module according to Embodiment 1 of the present description.

FIG. 12B is a cross-sectional view schematically illustrating an example of a state in which the solder bumps disposed on the circuit module according to Embodiment 1 of the present description are melted by reflow.

As illustrated in FIG. 12A, the solder bumps 70 are disposed in the recesses 32a of the circuit module 10.

Next, as illustrated in FIG. 12B, the solder bumps 70 are melted by reflow or another treatment.

The reflow conditions are not limited as long as the conditions enable the solder bumps 70 to be melted, and the temperature of 230° C. or higher and 270° C. or lower and the duration of 5 seconds or longer and 60 seconds or shorter are preferable.

As illustrated in FIG. 12B, since the solder bumps 70 and the molding resin 30 are not bonded to each other, a slight gap remains in each of the recesses 32a. On the other hand, the solder bumps 70 and the plating layers 60 formed on the stud electrodes 40 form an alloy and are thus bonded to each other.

In addition, when the solder bumps 70 are melted, the solder bumps 70 also wet-spread to the exposed side surfaces 42.

A height (a height denoted by a reference sign “H₄” in FIG. 12B) of the solder bumps 70 protruding from the recesses 32a can be adjusted by adjusting, for example, the positions of the exposed end surfaces 41 of the stud electrodes 40 and the mass of the solder bumps 70.

Next, a modification of the circuit module according to Embodiment 1 of the present description is described.

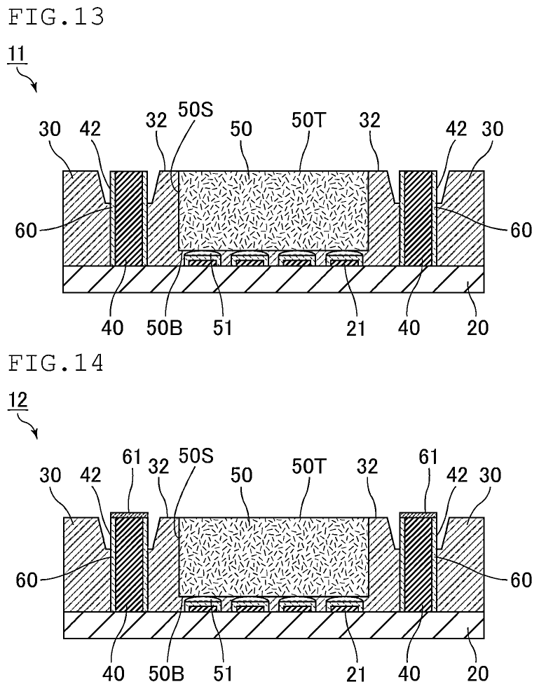

FIG. 13 is a cross-sectional view schematically illustrating a modification of the circuit module according to Embodiment 1 of the present description.

A circuit module 11 illustrated in FIG. 13 has the same configuration as the above circuit module 10 except that the exposed end surfaces 41 of the stud electrodes 40 are located on the same plane as the second main surface 32 and no plating layer 60 is formed on the exposed end surfaces 41.

Examples of a method for forming such circuit module 11 include the following method. The height He of the stud electrodes 40 made through the stud electrode constraint layer preparation step, the stud electrode constraint layer laminating step, and the baking step is made higher than the second main surface 32 of the circuit module 11 to be manufactured, and the stud electrodes 40 are polished in the polishing step together with the molding resin 30 and the electronic component 50.

Next, another modification of the circuit module according to Embodiment 1 of the present description is set forth.

FIG. 14 is a cross-sectional view schematically illustrating another modification of the circuit module according to Embodiment 1 of the present description.

A circuit module 12 illustrated in FIG. 14 has the same configuration as the above circuit module 11 except that plating layers 61 are formed on the exposed end surfaces 41 of the stud electrodes 40.

The circuit module 12 can be manufactured by performing a plating treatment on the exposed end surfaces 41 of the stud electrodes 40 in the circuit module 11 to thereby form the plating layers 61.

The plating layers 60 and the plating layers 61 may be made of the same type of metal, or may be made of different types of metals.

### Embodiment 2

Next, a circuit module according to Embodiment 2 of the present description is set forth.

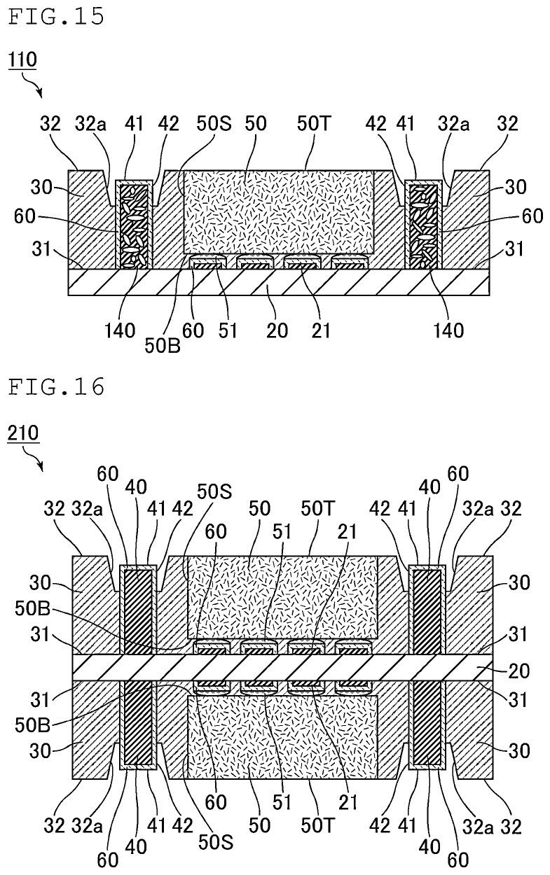

FIG. 15 is a cross-sectional view schematically illustrating an example of the circuit module according to Embodiment 2 of the present description.

A circuit module 110 illustrated in FIG. 15 has the same configuration as the above circuit module 10 except that stud electrodes 140 are porous bodies.

Generally, when the circuit module receives heat, the molding resin thermally expands and pushes the stud electrode. In addition, the stud electrode itself also thermally expands, and thermal stress is generated in the entire circuit module.

When the circuit module repeatedly receives heat, this thermal stress causes a crack inside the stud electrode or at a joint interface between the molding resin and the solder bump, or causes peeling between the stud electrode and the molding resin.

However, when the stud electrodes 140 are porous bodies as in the circuit module 110, the stud electrodes 140 have higher flexibility and can therefore absorb thermal stress.

Therefore, for example, even when the molding resin 30 expands by heat, the stud electrodes 140 can absorb the expanded volume.

As a result, it is possible to prevent the crack and peeling from occurring. That is, by forming the stud electrodes 140 to be porous bodies, the heat resistance of the circuit module is improved.

In the stud electrodes 140, the internal porosity is preferably 5 vol % to 40 vol %, more preferably 10 vol % to 35 vol %.

When the porosity is less than 5 volt, the heat resistance is hardly improved sufficiently.

When the porosity is more than 40 volt, the denseness of the stud electrode is lower, and the strength tends to be decreased. In addition, when the plating layer is formed on the stud electrode, the plating solution enters the voids, and solder burst is likely to occur when the solder bump is disposed or when the circuit module is mounted.

Examples of the method for producing the stud electrodes 140 that are porous bodies include a method in which resin particles are added to the stud electrode forming conductive paste in the stud electrode constraint layer preparation step described in the method for manufacturing the circuit module according to Embodiment 1 of the present description.

When resin particles are added to the stud electrode forming conductive paste, the resin particles are thermally decomposed in the baking step, and voids are generated in the parts where the resin particles were. As a result, the stud electrodes 140 can be made to be porous bodies.

The porosity of the stud electrodes 140 can be controlled by adjusting the type, size, and amount of the resin particles.

Examples of the resin particles include acrylic resin beads, polystyrene resin beads, and polypropylene resin beads.

In the stud electrodes 140, the pores forming the voids may communicate with other pores or may be closed pores. By adjusting the size and amount of the resin particles to be added to the stud electrode forming conductive paste, the pores can be made to communicate with other pores or can be made to be closed pores.

### Another Embodiment

In the circuit module according to Embodiment 1 and the circuit module according to Embodiment 2 described above, stud electrodes, a molding resin, and an electronic component are disposed only on one surface of a substrate.

However, in the circuit module of the present description, stud electrodes, a molding resin, and an electronic component may be disposed on both surfaces of a substrate.

Such a circuit module is described with reference to the drawing.

FIG. 16 is a cross-sectional view schematically illustrating an example of a circuit module according to another embodiment of the present description.

In a circuit module 210 illustrated in FIG. 16, also on the surface opposed to the surface of the substrate 20 on which the stud electrodes 40, the molding resin 30, and the electronic component 50 are disposed in the above circuit module 10, there may be similarly disposed stud electrodes 40, a molding resin 30, and an electronic component 50.

The circuit module according to the present description may be shipped after performing other processing such as appearance screening, characteristic screening, and taping.

In addition, the circuit module according to the present description may be manufactured in such a manner that an assembly of circuit modules is once produced and is then divided into individual pieces.

### EXAMPLES

### Example 1

### (Ceramic Green Sheet Preparation Step)

Powders of SiO₂, BaCO₃, Al₂O₃, and MnCO₃ as LTCC materials were adjusted to have the following compositions after baking: 54.9 parts by weight of SiO₂, 29.8 parts by weight of Bao, 11.5 parts by weight of Al₂O₃, and 3.8 parts by weight of MnOCO₃, which accounts for 100%. In addition, 10 parts by weight of polyvinyl butyral as a binder and 3 parts by weight of bis (2-ethylhexyl) phthalate (DOP) as a plasticizer were mixed, and a slurry was thereby prepared.

Next, the slurry was applied onto a carrier film to have a thickness of 0.050 to 0.100 mm to form a ceramic green sheet.

### (Stud Electrode Constraint Layer Preparation Step)

A slurry was prepared by mixing 88 parts by weight of Al₂O₃ as a sintering-resistant ceramic material powder, 9 parts by weight of polyvinyl butyral as a binder, and 3 parts by weight of DOP as a plasticizer.

Next, the slurry was applied onto a carrier film to have a thickness of 0.090 to 0.110 mm to prepare the constraining-layer green sheet according to Working example 1.

Next, a through-hole having a diameter of 0.200 mm was made in the constraining-layer green sheet.

Next, the stud electrode forming conductive paste according to Working example 1 was prepared by mixing 95 parts by weight of Cu as a conductive powder, 1.5 parts by weight of ethyl cellulose as a binder and a plasticizer, and 3.5 parts by weight of acrylic resin beads as resin particles.

Next, the through-hole of the constraining-layer green sheet was filled with the stud electrode forming conductive paste by screen printing to prepare the stud electrode constraint layer according to Working example 1. Two stud electrode constraint layers according to Working example 1 were prepared in the same manner.

### (Stud Electrode Constraint Layer Laminating Step)

Next, the two stud electrode constraint layers were laminated on the ceramic green sheet.

### (Baking Step)

Next, a stud electrode was prepared by performing baking in a low oxygen atmosphere under the condition of 950° C. for 1 hour.

In this step, the resin particles were thermally decomposed, and the stud electrode became a porous body.

The porosity of the stud electrode according to Working example 1 was 3 vol %. The stud electrode had a height of 0.160 mm.

### (Stud Electrode Constraint Layer Removal Step)

Next, the baked constraining-layer sheet was removed by sandblast.

### (Plating Step)

Next, a plating layer including Ni/Au was formed on the stud electrode by electroless plating.

### (Resin Sealing Step)

Next, an epoxy resin was used as a molding resin, and the stud electrode was sealed with the molding resin such that the thickness of the molding resin was 0.240 mm.

### (Polishing Step)

Next, a second main surface of the molding resin was polished by lap polishing such that the thickness of the molding resin was 0.20 mm.

### (Stud Electrode Exposing Step)

Next, a recess was formed in the second main surface of the molding resin by laser. At this time, the recess was formed at the position where the stud electrode was to be exposed.

The recess was formed to have a diameter of 0.250 mm and a depth of 0.050 mm.

After that, the part irradiated with the laser was preferably cleaned by a desmear treatment or the like to remove foreign matters.

Through the above steps, the circuit module according to Working example 1 was manufactured.

Thereafter, a solder bump of 0.011 g was disposed in the recess of the circuit module according to Working example 1, and the solder bump was melted by heating at 250° C., so that the solder bump was connected to the exposed end surface and the exposed side surface of the stud electrode.

### Examples 2 to 9

Stud electrodes according to Working examples 2 to 9 were prepared in the same manner as in Working example 1 except that the blending amount of the resin particles was changed such that the porosities had the same values as shown in Table 1, and a solder bump was disposed on each stud electrode.

TABLE 1

| | Porosity | Thermal shock |
|---|---|---|
| | (vol %) | index |
| Example 1 | 3 | 100 |
| Example 2 | 5 | 108 |
| Example 3 | 10 | 111 |
| Example 4 | 15 | 118 |
| Example 5 | 20 | 120 |
| Example 6 | 30 | 119 |
| Example 7 | 35 | 112 |
| Example 8 | 40 | 102 |
| Example 9 | 50 | 72 |

### (Heat Cycle Test)

After the circuit module according to each of the working examples in which the solder bump was disposed was subjected to cycles, in each of which the temperature was-40° C. to 85° C. and a retention time was 30 minutes, until a crack occurred in each stud electrode or solder portion, and the number of cycles until the crack occurred was measured. Based on each number of cycles, a thermal shock index was calculated. The results are shown in Table 1.

The thermal shock indices shown in Table 1 are represented by the ratios with respect to 100, which corresponds to the number of cycles until a crack occurred in the stud electrode having a porosity of 3 vol %.

Regarding the stud electrode according to Working example 9, solder burst occurred during the heat cycle test.

As shown in Table 1, it has been found that when the porosity of the stud electrode is 5 vol % to 40 vol %, occurrence of a cracks can be suitably reduced even when stress is generated by heat, and thermal stress resistance can be improved by about 10% to 20%.

### REFERENCE SIGNS LIST

10, 11, 12, 110, 210 circuit module
20 substrate
20a ceramic green sheet
21 electrode
21a unfired body for electrode
30 molding resin
31 first main surface
32 second main surface
32′ pre-second main surface
32a recess
40, 140 stud electrode
40a stud electrode forming conductive paste
41 exposed end surface
42 exposed side surface
50 electronic component
50B bottom surface of electronic component
50S side surface of electronic component
50T upper surface of electronic component
51 connection member
60, 61 plating layer
70 solder bump
80 baked constraining-layer sheet
80a constraining-layer green sheet
81 through-hole
83 stud electrode constraint layer

1. A circuit module comprising:
a substrate;
a stud electrode on a surface of the substrate;
a molding resin on the surface of the substrate and covering a periphery of the stud electrode, the molding resin including: a first main surface adjacent the surface of the substrate; and a second main surface opposed to the first main surface, the molding resin including a recess in the second main surface, the recess being located such that an end surface and a side surface of the stud electrode are exposed in the recess from the molding resin; and
a plating layer on the exposed side surface of the stud electrode.

2. The circuit module according to claim 1, wherein the plating layer is also on the exposed end surface of the stud electrode.

3. The circuit module according to claim 2, wherein the exposed end surface of the stud electrode is located on a same plane as the second main surface of the molding resin.

4. The circuit module according to claim 1, wherein the exposed end surface of the stud electrode is located on a same plane as the second main surface of the molding resin.

5. The circuit module according to claim 2, wherein the exposed end surface of the stud electrode is located closer to the substrate as compared to the second main surface of the molding resin.

6. The circuit module according to claim 1, wherein the exposed end surface of the stud electrode is located closer to the substrate as compared to the second main surface of the molding resin.

7. The circuit module according to claim 1, wherein a height of the exposed side surface of the stud electrode in a thickness direction of the molding resin is 5% to 30% of a thickness of the molding resin.

8. The circuit module according to claim 1, wherein a height of the exposed side surface of the stud electrode in a thickness direction of the molding resin is 10% to 25% of a thickness of the molding resin.

9. The circuit module according to claim 1, wherein a depth of the recess in a thickness direction of the molding resin is 10% to 50% of a thickness of the molding resin.

10. The circuit module according to claim 1, wherein a depth of the recess in a thickness direction of the molding resin is 20% to 45% of a thickness of the molding resin.

11. The circuit module according to claim 1, wherein the stud electrode comprises a porous body.

12. The circuit module according to claim 11, wherein the porous body has an internal porosity of 5 vol % to 40 vol %.

13. The circuit module according to claim 11, wherein the porous body has an internal porosity of 10 vol % to 35 vol %.

14. The circuit module according to claim 6, wherein the stud electrode comprises a porous body.

15. The circuit module according to claim 14, wherein the porous body has an internal porosity of 5 vol % to 40 vol %.

16. The circuit module according to claim 14, wherein the porous body has an internal porosity of 10 vol % to 35 vol %.

17. The circuit module according to claim 1, wherein an area inside a contour of a bottom surface of the recess of the second main surface as viewed from a direction perpendicular to the second main surface is 0.03 mm to 0.30 mm.

18. The circuit module according to claim 1, wherein the recess has a tapered shape.
